(19) United States
(12) Patent Application Publication
(10) Pub. No.: US 2025/0299879 A1
(43) Pub. Date: Sep. 25, 2025

(54) MULTILAYER CERAMIC CAPACITOR AND CIRCUIT BOARD

(71) Applicant: TAIYO YUDEN CO., LTD., Tokyo (JP)

(72) Inventors: Yoshinari TAKE, Tokyo (JP); Tomoki INOUE, Tokyo (JP); Takeshi SAKASHITA, Tokyo (JP); Takayuki TAKANO, Tokyo (JP); Yuka NAITO, Tokyo (JP); Ryo NAKAGAWA, Tokyo (JP)

(73) Assignee: TAIYO YUDEN CO., LTD., Tokyo (JP)

(21) Appl. No.: 19/083,838

(22) Filed: Mar. 19, 2025

(30) Foreign Application Priority Data
Mar. 25, 2024 (JP) 2024-047674

(51) Int. Cl. H01G 2/22; H01G 4/005; H01G 4/12; H01G 4/232; H01G 4/236; H01G 4/248; H01G 4/30

(52) U.S. Cl. CPC H01G 2/22; H01G 4/005; H01G 4/12; H01G 4/232; H01G 4/236; H01G 4/248; H01G 4/30

(57) ABSTRACT

One aspect of the present invention is a multilayer ceramic capacitor, including: a cuboid element body having a stack formed with alternating ceramic layers and internal electrodes made primarily of metal, a protective portion covering a surface of the stack, and a plurality of via conductors arranged so as to pass through the ceramic layers in the stacking direction of the stack, electrically connected to the internal electrodes, and having one end portion reaching the surface of the protective portion while the other end is covered by the protective portion, and a plurality of terminal electrodes arranged on at least a mounting face, which is a face that faces the circuit board when the multilayer ceramic capacitor is mounted on the circuit board, among faces that form the surfaces of the element body, and connected electrically to the via conductors, wherein an electrode is not arranged on the opposite face, which is the face opposing the mounting face, among the faces that form the surfaces of the element body, and a protruding portion is provided at a position where the side of the end portion of a via conductors covered by the protective portion is projected in the stacking direction of the stack.

### CROSS-REFERENCE TO RELATED APPLICATIONS

This application claims the benefit of Japanese Application No. 2024-047674, filed Mar. 25, 2024, in the Japanese Patent Office. All disclosures of the document named above are incorporated herein by reference.

### BACKGROUND OF THE INVENTION

### 1. Field of the Invention

The present invention relates to a multilayer ceramic capacitor and a circuit board.

### 2. Description of the Related Art

A wide variety of ceramic electronic components are used in high-frequency communication systems, such as in mobile phones. There is a demand for smaller and thinner ceramic electronic components, and multilayer ceramic capacitors are being considered to reduce the size and thickness of these components.

Patent Document 1 discloses a thin, damage-resistant multilayer ceramic capacitor in which via hole electrodes used to electrically connect the internal electrode layers and the terminal electrodes to each other have a void inside. In the multilayer ceramic capacitor disclosed in Patent Document 1, the terminal electrodes are formed on the top surface of the element body, which has a flat shape.

### PRIOR ART DOCUMENTS

### Patent Documents

Patent Document 1: JP 2020-72263 A

### SUMMARY OF THE INVENTION

### Problem(s) to be Solved by the Invention

The multilayer ceramic capacitor disclosed in Patent Document 1 has terminal electrodes formed only on the top surface among opposing top and bottom surfaces. In a multilayer ceramic capacitor with such a structure, the bottom surface, where terminal electrodes are not formed, is flat over the entire surface because there is no convexness caused by external electrodes. Therefore, during handling of individual capacitor chips in the manufacturing process, the bottom surface comes into contact with manufacturing equipment and tools, as well as other capacitor chips, etc., and the electrostatic charge increases due to the larger contact area. This causes transport malfunctions due to clinging, which lowers the yield during production. The electrostatic charge due to the flat bottom surface also increases when the cover tape is peeled from the carrier tape carrying the capacitor. Capacitor chips also cling to the peeled cover tape due to the increased electrostatic charge, resulting in lower yields during mounting.

It is an object of the present invention to solve this problem by providing a thin multilayer ceramic capacitor with a suppressed amount of static electricity generated during handling, and a circuit board carrying this thin multilayer ceramic capacitor.

### Means for Solving the Problem

As a result of extensive research conducted to solve this problem, the present inventors discovered that this object could be achieved by including protruding portions at the position corresponding to via conductors on the bottom surface, that is, the surface on which terminal electrodes are not formed, in a multilayer ceramic capacitor in which the internal electrodes are electrically connected to each other by way of via conductors. The present invention is a product of this discovery.

Specifically, a first aspect of the present invention that solves this problem is a multilayer ceramic capacitor, comprising: a cuboid element body having a stack formed with alternating ceramic layers and internal electrodes made primarily of metal, a protective portion covering a surface of the stack, and a plurality of via conductors arranged so as to pass through the ceramic layers in the stacking direction of the stack, electrically connected to the internal electrodes, and having one end portion reaching the surface of the protective portion while the other end is covered by the protective portion, and a plurality of terminal electrodes arranged on at least a mounting face, which is the face that faces the circuit board when the multilayer ceramic capacitor is mounted on the circuit board, among faces that form the surfaces of the element body, and connected electrically to the via conductors, wherein an electrode is not arranged on the opposite face, which is the face opposing the mounting face, among the faces that form the surfaces of the element body, and a protruding portion is provided at a position where the side of the end portion of the via conductor covered by the protective portion is projected in the stacking direction of the stack.

A second aspect of the present invention that solves this problem is a circuit board carrying the multilayer ceramic capacitor according to the first aspect.

### Effect of the Invention

The present invention is able to provide a thin multilayer ceramic capacitor with a suppressed amount of static electricity generated during handling, and a circuit board carrying this multilayer ceramic capacitor has been mounted.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic diagram (perspective view) showing the configuration of the multilayer ceramic capacitor in the first embodiment of the present invention.

FIG. 2 is a cross-sectional view (LT cross-sectional view) from A-A in FIG. 1.

FIG. 3A is a diagram used to explain the method for determining whether the opposing surface of a multilayer ceramic capacitor has protruding portions at positions where a side of the end portions of the via conductors covered by the protective portion is projected in the stacking direction of the stack.

FIG. 3B is a diagram used to explain the method for determining the protruding height in the central portion and peripheral portions of the protruding portions formed at positions where a side of the end portions of the via conductors covered by the protective portion is projected in the stacking direction of the stack on the opposing surface of a multilayer ceramic capacitor.

FIG. 4 is a schematic diagram (LT cross-sectional view) showing the configuration of the multilayer ceramic capacitor in the second embodiment of the present invention.

FIG. 5 is a schematic diagram (perspective view) showing the configuration of the multilayer ceramic capacitor in the third embodiment of the present invention.

### DETAILED DESCRIPTION OF THE EMBODIMENTS

The configuration and effects of the present invention will now be explained with technical concepts and with reference to the drawings. The mechanism of action includes conjecture, but correctness or incorrectness of this conjecture does not limit the present invention.

### Multilayer Ceramic Capacitor

### First Embodiment

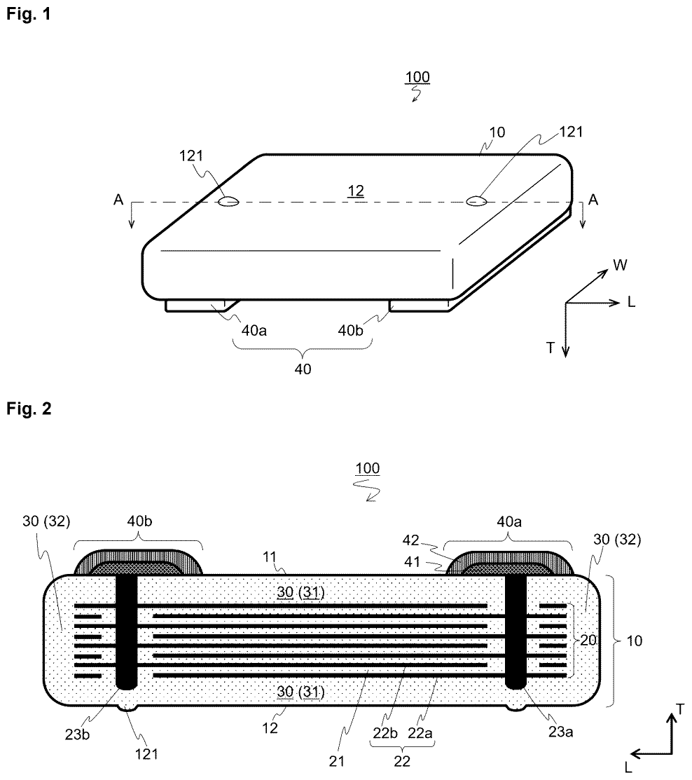

An embodiment of a multilayer ceramic capacitor related to the first aspect of the present invention is shown in FIG. 1 and FIG. 2 as the first embodiment. Note that FIG. 1 is shown with the height direction (T-axis direction) reversed from FIG. 2 to make it easier to see the protruding portions formed on the opposite face, which will be described later. The multilayer ceramic capacitor 100 in the first embodiment has a cuboid shape and has a pair of planes that are orthogonal to each other on three mutually orthogonal axes, namely, the L-axis, which is the length direction, the W-axis, which is the width direction, and the T-axis, which is the height direction. The cuboid is not limited to a cuboid shape defined mathematically, but can be any shape that is recognized as being cuboid when the overall shape is observed. For this reason, objects with rounded edges and corners, curved edges, and surfaces with a small degree of curvature also fall under the category of “cuboid” in the present disclosure. The length (L), width (W), and height (T) dimensions of the ceramic capacitor 100 can each independently take any value.

In an example of dimensions for a multilayer ceramic capacitor 100, the L-direction dimension is 200 μm or more and 2000 μm or less, the W-direction dimension is 100 μm or more and 2000 μm or less, the T-direction dimension is 30 μm or more and 220 μm or less, and the W/L value, which is the ratio of the W-direction dimension to the L-direction dimension, is 0.3 or more and 1.0 or less. Preferably, the L-direction dimension is 400 μm or more and 1200 μm or less, the W-direction dimension is 400 μm or more and 1200 μm or less, the T-direction dimension is 40 μm or more and 150 μm or less, and the W/L value, which is the ratio of the W-direction dimension to the L-direction dimension, is 0.4 or more and 1.0 or less. A T-direction dimension of 100 μm or less is preferred in that it is less likely to be impose design constraints on the circuit board on which it is mounted.

In the multilayer ceramic capacitor 100 of the first embodiment, as shown schematically in cross-sectional view in FIG. 2 (LT cross-sectional view), the element body 10 has ceramic layers 21, internal electrodes 22 made primarily of metal, which are alternately stacked in the T direction to form a stack 20, and a protective portion 30 that covers the surfaces of the stack 20. The internal electrodes 22 include internal electrodes 22a of one polarity that are electrically connected to each other, and internal electrodes 22b of a different polarity than internal electrodes 22a that are electrically connected to each other.

On the surfaces of the element body 10, a protective portion 30 is arranged to cover the surfaces of the stack 20. The protective portion 30 includes a cover portion 31 arranged on a plane perpendicular to the T direction, and margin portions 32 arranged on planes perpendicular to the W and L directions.

The element body 10 has a plurality of via conductors 23 arranged so as to pass through the ceramic layers 21 in the stacking direction of the stack 20 and connect electrically to internal electrodes 22, with one end reaching the surface of the protective portion 30 (cover portion 31) and the other end remaining covered by the protective portion 30 (cover portion 31). The via conductors 23 include via conductor 23a electrically connected to internal electrodes 22a and via conductor 23b electrically connected to internal electrodes 22b. The multilayer ceramic capacitor 100 shown in FIG. 1 and FIG. 2 has two via conductors 23, but the number of via conductors in the multilayer ceramic capacitor of the first aspect of the invention is not limited to this example.

The multilayer ceramic capacitor 100 in the first embodiment has a plurality of terminal electrodes 40 electrically connected to via conductors 23 (23a, 23b), which are located at least on the mounting face 11, which is the face opposite to the circuit board when the multilayer ceramic capacitor is mounted on the circuit board, among the faces forming the surface of the element body 10. The terminal electrodes 40 includes terminal electrode 40a electrically connected to via conductor 23a and terminal electrode 40b electrically connected to via conductor 23b. The multilayer ceramic capacitor 100 shown in FIG. 1 and FIG. 2 has two terminal electrodes 40, but the number of terminal electrodes in the multilayer ceramic capacitor in the first aspect of the invention is not limited to this example.

Meanwhile, among the faces forming the surface of the element body 10, no electrodes are located on the opposite face 12, which is the surface opposite to the mounting face 11. The opposite face 12 has protruding portions 121 positioned where a side of the end portions of the via conductors 23 (23a, 23b) covered with the protective portion 30 (cover portion 31) is projected in the stacking direction of the stack 20.

The thickness of the element body 10, which is obtained by subtracting the thickness of the terminal electrodes 40 (40a, 40b) from the T-direction dimension of the multilayer ceramic capacitor 100, is, for example, 20 μm or more and 200 μm or less, and preferably 30 μm or more and 180 μm or less.

The following is a detailed description of each component that constitutes the multilayer ceramic capacitor 100 in the first embodiment.

### Ceramic Layers

The ceramic layers 21 are formed of a ceramic. The composition of the ceramic is not particularly limited, as long as it forms a dense ceramic layer 21 during simultaneous firing with the internal electrodes 22 described below, and can be selected as appropriate depending on the characteristics required of the multilayer ceramic capacitor. Examples of ceramic compositions include those with barium titanate (BaTiO₃) as the main component, those with strontium titanate (SrTiO₃) as the main component, and those with a perovskite-type structure Ba_{1-x-y}CaₓSr_{y}Ti_{1-z}Zr_{z}O₃ as the main component. The ceramic may contain additive elements in addition to the main components mentioned above. Examples of additive elements include at least one selected from Mo, Nb, Ta, W, Mg, Mn, V, and Cr, rare earth elements (Y, Sm, Eu, Gd, Tb, Dy, Ho, Er, Tm, and Yb), and Co, Ni, Li, B, Na, K, and Si. The additive element may be included in the form of a compound, such as an oxide, nitride, or carbide, or it may be included as the element in its pure form. In addition, the additive elements may be present in a solid solution with the main component mentioned above, or may form a different phase with the element that constitutes the main component or another additive element.

### Internal Electrodes

The internal electrodes 22 (22a, 22b) are composed primarily of metal. There are no particular restrictions on the type of metal, and nickel (Ni), copper (Cu), palladium (Pd), platinum (Pt), silver (Ag), gold (Au), or alloys of these metals can be used. Among these, those with nickel (Ni) as the main component element are preferred because of their high heat resistance, which allows the firing temperature to be increased during firing together with the ceramic layers 21 to form dense ceramic layers 21, and because they are relatively inexpensive. In this document, the term “main component element” refers to the element with the highest content, expressed as an atomic percentage (at %).

In addition to metal, the internal electrodes 22 (22a, 22b) may also contain ceramic particles having a composition similar to that of the ceramic that constitutes the ceramic layers 21, or glass components.

### Protective Portion

The protective portion 30 has the function of protecting the ceramic layers 21 and internal electrodes 22. The material in the protective portion 30 is not limited as long as it has high electrical insulation properties and low permeability to moisture and other degradation factors. From the standpoint of ensuring uniform shrinkage during firing when manufacturing the multilayer ceramic capacitor 100, and relieving internal stress inside the multilayer ceramic capacitor 100, the main component of the protective portion 30 is preferably the same as the ceramic forming the ceramic layers 21.

### Via Conductors

Like the internal electrodes 22 (22a, 22b), the via conductors 23 (23a, 23b) are made primarily of metal. The metals that can be used are the same as those used in the internal electrodes 22 (22a, 22b) mentioned above. The composition of the via conductors may be different from that of the internal electrodes 22 (22a, 22b), but is preferably the same as that of the internal electrodes 22 (22a, 22b). By making the composition of the via conductors (23a, 23b) and the internal electrode 22 (22a, 22b) the same, the degree of shrinkage caused by firing during the manufacture of the multilayer ceramic capacitor 100 is uniform, which helps to suppress deformation, and the resistivity of the conductive paths of the multilayer ceramic capacitor 100 is uniform, which helps to suppress localized heat generation during use.

The diameter of the via conductors 23 (23a, 23b) is not particularly limited, but from the standpoint of reducing electrical resistance and suppressing heat generation during circuit operation while maintaining the capacitance of the multilayer ceramic capacitor 100, the diameter is preferably 5 μm or more and 100 μm or less, and more preferably 10 μm or more and 50 μm or less. These preferred diameters are also preferred in that the diameter of the protruding portions 121 formed in the opposing surface 12 can be effective in suppressing electrostatic charging.

The via conductors 23 (23a, 23b) preferably have protruding portions protruding in the stacking direction at the end portion on the side of opposite face 12 in the cross-section parallel to the stacking direction of the stack 20, that is, on the end portion of the side covered by the protective portion 30 (cover portion 31). The protruding portions at the end portions of the via conductors 23 (23a, 23b) on the side of opposite face 12 are formed as a result of the conductor paste for forming the via conductors remaining without moving toward the mounting face 11, and the green sheet for forming the cover portion being pushed back when the green sheet for forming the cover portion on the opposite face 12 is pressure bonded in the manufacturing process of the multilayer ceramic capacitor 100, which is described later. The fact that the end portions of the via conductors 23 (23a, 23b) on the side of opposite face 12 have protruding portions indicates high adhesion between the via conductors 23 (23a, 23b) and the adjacent cover portion 31, the ceramic layers 21, and internal electrodes 22 (22a, 22b). This results in a multilayer ceramic capacitor 100 with high mechanical strength.

### Terminal Electrodes

The material of the terminal electrodes 40 (40a, 40b) is not limited as long as the material has electrical conductivity. Examples of materials include metals such as nickel (Ni), copper (Cu), tin (Sn), palladium (Pd), platinum (Pt), silver (Ag), and gold (Au), alloys containing any of these as the main component, and electrically conductive resins.

The terminal electrodes 40 (40a, 40b) may be composed of a base conductor 41 in contact with the element body 10 and a plated conductor 42 formed on the surface of the base conductor 41. Terminal electrodes 40 (40a, 40b) with this structure can improve adhesion of the element body 10 with the base conductor 41, and improve the solder wettability when mounted on the circuit board using the plated conductor 42.

An example of a material for the base conductor 41 is Ni. The thickness of the base conductor 41 can be 0.1 μm or more and 10 μm or less, and is preferably 0.5 μm or more and 5 μm or less.

The plated conductor 42 may be formed with a single layer or with multiple layers. When multiple layers are formed in the plated conductor 42, two to four layers is preferred. In one example of the materials and structure of the plated conductor 42, a structure is formed in the order Cu, Ni, and Sn. The thickness of the plated conductor 42 can be 1 μm or more and 20 μm or less, and 3 μm or more and 10 μm or less is preferred.

### Protruding Portions

The protruding portions 121 formed in the opposite face 12 are positioned at the end of the via conductors 23 (23a, 23b) on the side covered by the protective portion 30 (cover portion 31), projected in the stacking direction of the stack 20. This reduces the amount of static electricity generated on the opposite face 12 when handling the multilayer ceramic capacitor 100. This is believed to be due to the presence of the protruding portions 121, which reduce the area of the region in contact with other members and elements. Because the via conductors 23 are spaced apart at an appropriate distance from the end faces of the multilayer ceramic capacitor 100 and other via conductors 23 to prevent short circuits, the formation positions of the protruding portions 121 on the opposite face 12 correspond to the via conductors 23 and allow the protruding portions 121 to be spaced apart at an appropriate distance from each other. This is believed to contribute to the suppression of static electricity generation. Because the protruding portions 121 formed at the projected positions of the end portions of the via conductors 23 (23a, 23b) also indicate the positions of the terminal electrodes 40 (40a, 40b) formed on the mounting face 11, when mounting the multilayer ceramic capacitor 100 on a circuit board, the lands and terminal electrodes 40 (40a, 40b) can be aligned using the protruding portions 121 as guideposts.

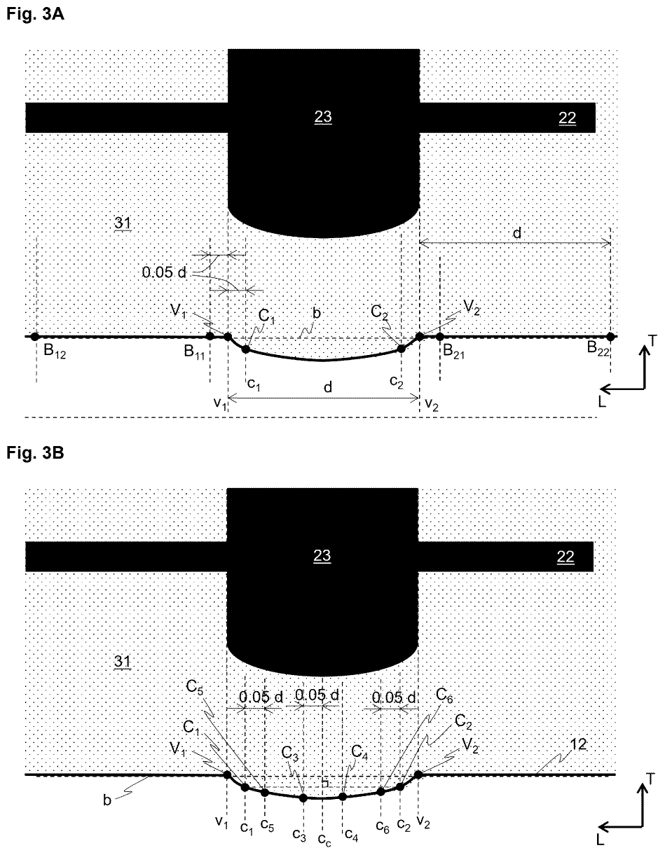

The following process is used to determine whether the opposite face 12 has protruding portions 121 at the positions where the end portions of the via conductors 23 (23a, 23b) on the side covered by the protective portion 30 (cover portion 31) are projected in the stacking direction of the stack 20. First, the terminal electrodes 40 formed on the mounting face 11 of the multilayer ceramic capacitor 100 are removed to expose the via conductors 23 on the mounting face 12. Removal methods for the terminal electrodes 40 include polishing and acid dissolution. Next, the multilayer ceramic capacitor 100 is cut along a plane parallel to the stacking direction, passing near centroid of a via conductor 23 exposed on the mounting face 11 to prepare an inspection sample. The inspection sample may be prepared by polishing the face perpendicular to the mounting face 11 near the centroid of a via conductor 23 exposed on the mounting face 11. Next, the inspection sample is embedded in resin so that the cut surface is exposed, and the cut surface is mirror polished. Next, the mirror-polished cut surface is observed with an optical microscope or scanning electron microscope (SEM) to obtain an image in which the opposite face 12 and the via conductor 23 are in the same field of view, as shown in FIG. 3A. Next, in the acquired image, line segments v₁ and v₂ defining both sides of the via conductor 23 are drawn, and the obtained line segments are extended to the opposite face 12. Next, the distance d between V₁ and V₂ is measured, where V₁ is the intersection of line segment v₁ with the opposite dace 12 and V₂ is the intersection of line segment v₂ with the opposite face 12. Next, in the acquired image, line segment c₁, which is parallel to line segment v₁, located closer to the center of the via conductor 23 than line segment v₁, and at a distance of 0.05 d from line segment v₁, is drawn, and line segment c₂, which is parallel to line segment v₂, located closer to the center of via conductor 23 than line segment v₂, and whose distance from line segment v₂ is 0.05 d is drawn, where intersection of line segment c₁ with the opposite face 12 is C₁, and the intersection of line segment c₂ with the opposite face 12 is C₂. Next, in the image, a line segment parallel to line segment v₁ and at a distance 0.05 d from line segment v₁ on the opposite side of point C₁ to point V₁ is drawn, where B₁₁ is the intersection of the line segment and the opposite face 12, and a line segment parallel to line segment v₁ and at a distance d from line segment v₁ on the opposite side of point C₁ to point V₁ is drawn, where B₁₂ is the intersection of the line segment and the opposite face 12. Also, in the image, a line segment on the opposite side of point C₂ to point V₂, parallel to line segment v₂ and at a distance of 0.05 d from line segment v₂ is drawn, where B₂₁ is the intersection of the line segment and the opposite face 12, and on the opposite side of point C₂ to V₂, a line segment is drawn parallel to line segment v₂ and at a distance d from line segment v₂, where B₂₂ is the intersection of the line segment and the opposite side 12. Then, a line segment b is drawn that overlaps each of the regions located between points B₁₁ and B₁₂ and between points B₂₁ and B₂₂ on the opposite face 12. When the region of the opposite face 12 between points C₁ and C₂ is located opposite the via conductor 23 relative to line segment b, it is determined that the opposite face 12 has a protruding portion 121 located where the end portion of the via conductor 23 on the side covered by the protective portion 30 (cover portion 31) is projected in the stacking direction of the stack 20. In drawing line segment v₁, line segment v₂, and line segment b, if the side face or the opposite face 12 of the via conductor 23 observed in the image is curved or a polyline, the curve or polyline is linearly approximated as a line segment.

The number of protruding portions 121 formed on the opposite face 12 is not limited, but from the standpoint of enhancing the antistatic effect of the opposite face 12, three or more protruding portions are preferably formed, and four or more protruding portions are more preferably formed.

The protruding portions 121 preferably have a circular or oval shape when viewed from the direction perpendicular to the opposite face 12. This prevents cracking on the opposite face 12 when stress is applied to the multilayer ceramic capacitor 100. This is probably because stress is less likely to be concentrated at specific points on the periphery of a protruding portion 121.

The protruding portions 121 preferably have a greater protruding height in the central portion than in the peripheral portion. This can further reduce the amount of static electricity generated on the opposite face 12 when handling the multilayer ceramic capacitor 100. This is probably due to the fact that the area of the region in contact with other members and elements is reduced compared to when the protruding height is constant. Here, the protruding portions 121 preferably have a shape in which the rising amount decreases as the central portion is approached from the peripheral portion, as this significantly suppresses the occurrence of cracks in the cover portion 31, at the interface between the via conductors 23 (23a, 23b) and the cover portion 31, at the interface between the via conductors 23 (23a, 23b) and the internal electrodes 22 (22a, 22b), and at the interface between the via conductors 23 (23a, 23b) and the ceramic layers 21. This is probably due to the fact that the direction of the normal on the surface of the protruding portions 121 varies from position to position, which suppresses stress concentration at specific points.

The protruding height in the central portion of the protruding portions 121 is preferably 0.1 μm or more and 10 μm or less, and more preferably 0.2 μm or more and 1.0 μm or less. A protruding height of 0.1 μm or more in the central portion will have a pronounced antistatic effect as described above. Meanwhile, a protruding height in the central portion of 10 μm or less suppresses the generation of cracks in the cover portion 12, at the interface between the via conductors 23 (23a, 23b) and the cover portion 31, at the interface between the via conductors 23 (23a, 23b) and the internal electrodes 22 (22a, 22b), and at the interface between the via conductors 23 (23a, 23b) and the ceramic layers 21.

The protruding heights of a protruding portion 121 in the central and peripheral portions are determined using the following process. First, in accordance with the process used to determine the presence or absence of a protruding portion 121 in the opposite face 12 described above, a microscopic image is acquired and line segment v₁, line segment v₂, point V₁, point V₂, line segment c₁, line segment c₂, point C₁, point C₂ and line segment b are drawn in the image. Next, perpendicular bisector c_{c} of line segment C₁C₂ is drawn in the image, as shown in FIG. 3B. Next, two line segments c₃ and c₄ are drawn parallel to line segment c_{c} and at a distance of 0.05 d from line segment c_{c}, with C₃ and C₄ being the intersections with the opposite face 12. Next, any five points are selected from the region between points C₃ and C₄ on the opposite face 12, and the distance between each of these points and line segment b is measured, respectively. The average of the five measurements is then calculated, and the value obtained by dividing the average by the magnification factor of the microscopic image is the protruding height in the central portion of the protruding portion 121. Next, in the image, as shown in FIG. 3B, line segment c₅ is drawn, which is parallel to line segment c₁, located closer to line segment Cc than line segment c₁, and is 0.05 d from line segment c₁, and line segment c₆ is drawn, which is parallel to line segment c₂, located on the cc side of line segment c₂, and is 0.05 d from line segment c₂, where C₅ is the intersection of line segment c₅ with the opposite face 12 and C₆ is the intersection of line segment c₆ with the opposite face 12. Next, any three points are selected from the region between points C₁ and C₅ on the opposite face 12 and any three points from the region between points C₂ and C₆ on the opposite face 12, and the distance between each of these points and line segment b is measured, respectively. The average of the six measurements is then calculated, and the value obtained by dividing the average by the magnification factor of the microscopic image is the protruding height in the peripheral portion of the protruding portion 121.

### Second Embodiment

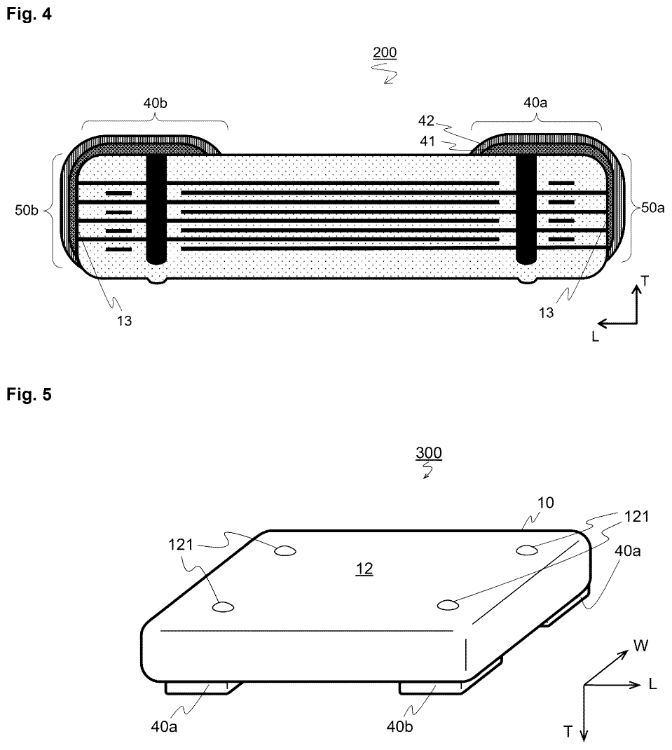

In another embodiment (second embodiment) of the multilayer ceramic capacitor in the first aspect of the invention, the internal electrodes are drawn out on a face perpendicular to the mounting face, and external electrodes are placed on the face from which the internal electrodes are drawn out (drawn-out face), so that the internal electrodes are electrically connected to each other via the external electrodes. An example of a multilayer ceramic capacitor 200 in the second embodiment is shown in FIG. 4. FIG. 4 shows an example in which two faces opposite each other are used as drawn-out faces, but the number of drawn-out faces is not limited to this example. FIG. 4 shows an example of terminal electrodes 40 (40a, 40b) extending to drawn-out face 13 forming external electrodes 50 (50a, 50b), but external electrodes 50 (50a, 50b) may be formed separately from terminal electrodes 40 (40a, 40b). In the multilayer ceramic capacitor 200, the current flowing through the internal electrodes 22 (22a, 22b) is divided between via conductors 23 (23a, 23b) and external electrodes 50 (50a, 50b), resulting in smaller current flowing through individual via conductors 23 (23a, 23b) and external electrodes 50 (50a, 50b). This reduces heat generation during operation.

### Third Embodiment

In another embodiment (the third embodiment) of the multilayer ceramic capacitor in the first aspect of the invention, the number of terminal electrodes located on the mounting face is four or more, and each terminal electrode has a different polarity from the terminal electrodes that are closest to it on the mounting face. An example of the third embodiment of a multilayer ceramic capacitor 300 is shown in FIG. 5. While FIG. 5 shows an example in which the number of terminal electrodes 40 arranged on the mounting face 11 is four, the number of terminal electrodes arranged on the mounting face is not limited to this example. Because the multilayer ceramic capacitor 300 has at least the same number of via conductors 23 (23a, 23b) as terminal electrodes and the same number of protruding portions 121 formed on the opposite face 12 as via conductors 23 (23a, 23b), electrostatic charging of the opposite face 12 is more effectively suppressed. Also, because the multilayer ceramic capacitor 300 is configured so that the direction of the current flowing through the via conductors (not shown) electrically connected to each terminal electrode 40 (40a, 40b) is in the opposite direction between conductors that are nearest to each other, the magnetic fields generated by the current cancel each other out, reducing the equivalent series inductance (ESL). These effects are more pronounced when the multilayer ceramic capacitor 300 has a mounting face 11 that is nearly square in shape, that is, when the value of W/L, which is the ratio of W to L, is between 0.8 and 1, where, among the two faces parallel to the stacking direction of the stack and facing each other, one spacing, or dimension in the L direction, is L μm, and the other spacing, or dimension in the W direction, is W μm (provided L≥W).

### Method for Manufacturing Multilayer Ceramic Capacitor

A multilayer ceramic capacitor in the first aspect of the present invention can be manufactured by the procedure described below.

### (A) Preparation of Ceramic Powder

First, the ceramic powder is prepared. Commercially available ceramic powders can be used if appropriate. When the ceramic powder is prepared by the user, raw powder materials including their constituent elements are mixed at a predetermined ratio and pre-fired (provisionally fired). Additives such as the additive elements and firing aids may be added when mixing the raw powder materials at predetermined ratios, or the additives may be included to the powder after provisional firing.

### (B) Preparation of the Green Sheet

Next, the ceramic powder is mixed with a binder and dispersant to prepare a slurry, which is then formed into a sheet to obtain a green sheet.

The binder used should be the one that can maintain the shape of the green sheet and that can volatilize without leaving behind carbon or other residues in the binder removal step prior to firing. Examples of binders that can be used include polyvinyl alcohol-based, polyvinyl butyral-based, cellulose-based, urethane-based, and vinyl acetate-based binders. The amount of binder used is not limited, but since it is removed in a subsequent step, the amount of binder used is preferably minimized to the extent that the desired moldability and shape retention can be obtained, in order to reduce raw material costs.

The dispersant used should be the one that can keep the previously fired powder and the binder from agglomerating and should be easily removed by volatilization or other means after formation of the green sheet described below. Examples of dispersants that can be used include water and alcohol-based solvents.

Components that adjust the properties of the slurry, such as dispersants, plasticizers, and thickeners, may be added to the slurry.

The method used to mix the mixed powder with the binder and dispersant is not limited as long as each component is uniformly mixed and impurities are kept from being mixed in. One example is ball mill mixing.

Methods that can be used to form the prepared slurry into a sheet to obtain a green sheet include any method common in the art, such as the doctor blade method and the die coating method.

### (C) Formation of the Internal Electrode Pattern

Next, an internal electrode pattern containing metal is formed on the green sheet. The internal electrode pattern can be formed by printing or coating internal electrode paste in a predetermined pattern, or by forming a metal film in a predetermined pattern by vapor deposition or sputtering deposition. The internal electrode pattern should be formed leaving a sufficient margin to ensure electrical insulation where there is no contact with the via conductor pattern formed later.

When forming an internal electrode pattern using an internal electrode paste, the internal electrode paste is obtained by mixing metal particles with a vehicle in a three-roll mill. In addition to the components mentioned above, the internal electrode paste may also contain glass frit or ceramic powder.

The type and amount of binder and solvent included in the vehicle are not limited, and are preferably selected as appropriate after taking into consideration the viscosity of the internal electrode paste, ease of handling, and compatibility with the green sheet.

Printing of the internal electrode paste on the green sheet can be performed, for example, using a screen mask with a predetermined internal electrode pattern. During printing, a space, that will become the margin portion when made into a multilayer ceramic capacitor, can be left.

### (D) Preparation of the Green Stack

Next, green sheets with internal electrode patterns are stacked in a predetermined number of layers, and the green sheets are pressure-bonded to obtain a green stack. Stacking and pressure bonding can be performed using any method common in the art, such as pressing the stacked green sheets together in the stacking direction while heating, and thermo-compression bonding the green sheets together by the action of the binder.

When performing stacking and pressure bonding, a green sheet may be added to the end in the stacking direction to serve as a cover portion when made into a multilayer ceramic capacitor. At this time, the green sheet that is added may have the same or a different composition from the green sheets on which an internal electrode pattern has been printed. From the standpoint of matching the shrinkage rate during firing, the composition of the green sheet that is added is preferably the same or similar to the composition of the green sheets on which the internal electrode precursors have been arranged.

### (E) Formation of the Via Conductor Pattern

Next, holes are formed in the green stack, and the holes are filled with conductive paste to form a via conductor pattern. When filling with conductive paste, the conductive paste should be filled so that it protrudes (rises) beyond the surface height of the green stack on the side that will be the opposite face when made into a multilayer ceramic capacitor. A method common in the art such as a drill or laser can be used to form the holes. Among these, the use of a laser is preferred because of its ability to form smooth machined surfaces. A method common in the art such as injection with a syringe or printing with a metal mask can be used to fill the holes with conductor paste. Among these, printing with a metal mask is preferred because of its superiority in filling small-diameter holes. As for the components in the conductor paste, the same as those in the internal electrode paste can be used, and the amount of each component should be determined after taking into consideration the hole filling properties.

### (F) Pressure Bonding of the Cover Portion Forming Green Sheet

Next, the green sheet for forming the cover portion is pressure bonded to the face of the green stack where the conductive paste protrudes. At this time, the green sheet for forming the cover portion is raised to conform to the protruding shape of the conductor paste, forming protruding portions.

### (G) Formation of the Terminal Electrode Pattern

Next, a terminal electrode pattern is formed on the face opposite the face to which the green sheet for forming the cover portion was pressure bonded. The terminal electrode pattern can be formed by printing or applying terminal electrode paste or by forming a metal film by vapor deposition or sputtering deposition. The terminal electrode pattern may be formed using a mask with a predetermined pattern or may be formed out of a paste film or metal film over the entire mounting face of the green stack, by removing the portions outside of the terminal electrode pattern. Face milling and barrel polishing can be used to remove the portions outside of the terminal electrode pattern. When terminal electrode paste is used to form the terminal electrode pattern, the same components as those in the internal electrode paste described above can be used, and the amount of each component is determined so that a uniform pattern can be obtained at a predetermined thickness.

### (H) Preparing Pre-Fired Chips

Next, the green stack is separated into units in the shape of individual multilayer ceramic capacitors to obtain chips prior to firing. Means commonly used to separate a green stack into individual capacitors include dicing saws and laser cutting machines. After the green stack has been separated into units to form a face on which the internal electrode precursor is exposed, the face may be coated with a material for forming a margin portion to complete the pre-fired chips.

### (I) Removing the Binder

The resulting pre-fired chips are then heated to volatilize and remove the binder. Heating conditions should be set as appropriate after taking into consideration the amount and volatilization temperature of the binder. One example is to hold temperatures from 200° C. to 500° C. for 5 to 20 hours in a nitrogen (N₂) atmosphere.

### (J) Firing the Pre-Fired Chips

Next, the pre-fired chips with the binder removed are heated to a predetermined temperature for firing. When setting the firing conditions, the firing properties of the ceramic powder and the heat and oxidation resistance of the metals in the internal electrode pattern, via conductor pattern, and terminal electrode pattern are preferably taken into consideration. Examples of firing conditions include holding the chips at 1100° C. to 1400° C. for 10 minutes to 2 hours in a reducing atmosphere of nitrogen (N₂), hydrogen (H₂), and water vapor (H₂O). After firing, re-oxidation treatment may be performed in a nitrogen (N₂) gas atmosphere or in a low-oxygen atmosphere kept at 600° C. to 1000° C.

The fired body thus obtained may be used as a multilayer ceramic capacitor as is, or it may be used as a multilayer ceramic capacitor after a conductive layer has been formed on the surface of the terminal electrode pattern by plating.

### Circuit Board

The circuit board in the second aspect of the invention has a mounted multilayer ceramic capacitor in the first aspect. This circuit board can be installed in a small space because the multilayer ceramic capacitor is a thin and has no electrodes on the opposite side.

The following technologies are also disclosed in the present specification.

### Addendum 1

A multilayer ceramic capacitor, comprising:
a cuboid element body having
   a stack formed with alternating ceramic layers and internal electrodes made primarily of metal,
   a protective portion covering a surface of the stack, and
   a plurality of via conductors arranged so as to pass through the ceramic layers in the stacking direction of the stack, electrically connected to the internal electrodes, and having one end portion reaching the surface of the protective portion while the other end is covered by the protective portion, and
a plurality of terminal electrodes arranged on at least a mounting face, which is the face that faces the circuit board when the multilayer ceramic capacitor is mounted on the circuit board, among faces that form the surfaces of the element body, and connected electrically to the via conductors,
   wherein an electrode is not arranged on the opposite face, which is the face opposing the mounting face, among the faces that form the surfaces of the element body, and
   a protruding portion is provided at a position where the side of the end portion of a via conductor covered by the protective portion is projected in the stacking direction of the stack.

### Addendum 2

The multilayer ceramic capacitor according to (Addendum 1), wherein the protruding portions are present in three or more locations.

### Addendum 3

The multilayer ceramic capacitor according to (Addendum 1) or (Addendum 2), wherein the protruding portions have a circular or oval shape when viewed from the direction perpendicular to the opposing surface.

### Addendum 4

The multilayer ceramic capacitor according to any of (Addendum 1) to (Addendum 3), wherein the via conductor has a protruding portion protruding in the stacking direction at the end portion on the side of the opposite face in a cross-section parallel to the stacking direction of the stack.

### Addendum 5

The multilayer ceramic capacitor according to any of (Addendum 1) to (Addendum 4), wherein the protruding portions on the opposite face protrude higher at the central portion than at the peripheral portion.

### Addendum 6

The multilayer ceramic capacitor according to (Addendum 5), wherein the protruding height of the central portion is 0.1 μm or more and 10 μm or less.

### Addendum 7

The multilayer ceramic capacitor according to any of (Addendum 1) to (Addendum 6), wherein the dimension in the stacking direction is less than 100 μm.

### Addendum 8

A circuit board carrying the multilayer ceramic capacitor according to any one of (Addendum 1) to (Addendum 7).

### INDUSTRIAL APPLICABILITY

The present invention is able to provide a thin multilayer ceramic capacitor with a reduced amount of static electricity generated during handling. Such multilayer ceramic capacitors are useful in terms of realizing high yields because they improve alignment accuracy during mounting on a circuit board.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A multilayer ceramic capacitor, comprising:
a cuboid element body having
a stack formed with alternating ceramic layers and internal electrodes made primarily of metal,
a protective portion covering a surface of the stack, and
a plurality of via conductors arranged so as to pass through the ceramic layers in the stacking direction of the stack, electrically connected to the internal electrodes, and having one end portion reaching the surface of the protective portion while the other end is covered by the protective portion, and
a plurality of terminal electrodes arranged on at least a mounting face, which is a face that faces the circuit board when the multilayer ceramic capacitor is mounted on the circuit board, among faces that form the surfaces of the element body, and connected electrically to the via conductors,
wherein an electrode is not arranged on the opposite face, which is the face opposing the mounting face, among the faces that form the surfaces of the element body, and
a protruding portion is provided at a position where the side of the end portion of a via conductor covered by the protective portion is projected in the stacking direction of the stack.

2. The multilayer ceramic capacitor according to claim 1, wherein the protruding portions are present in three or more locations.

3. The multilayer ceramic capacitor according to claim 1, wherein the protruding portions have a circular or oval shape when viewed from the direction perpendicular to the opposing surface.

4. The multilayer ceramic capacitor according to claim 1, wherein the via conductor has a protruding portion protruding in the stacking direction at the end portion on the side of the opposite face in a cross-section parallel to the stacking direction of the stack.

5. The multilayer ceramic capacitor according to claim 1, wherein the protruding portions on the opposite face protrude higher at the central portion than at the peripheral portion.

6. The multilayer ceramic capacitor according to claim 5, wherein the protrusion height of the central portion is 0.1 μm or more and 10 μm or less.

7. The multilayer ceramic capacitor according to claim 1, wherein the dimension in the stacking direction is less than 220 μm.

8. The multilayer ceramic capacitor according to claim 1, wherein the dimension in the stacking direction is less than 100 μm.

9. A circuit board carrying the multilayer ceramic capacitor according to claim 1.
